(19) United States
(12) Patent Application Publication
(10) Pub. No.: US 2016/0363258 A1
(43) Pub. Date: Dec. 15, 2016

(54) MOBILE ELECTRONIC DEVICE SUPPORT SYSTEMS, APPARATUSES AND METHODS

(71) Applicant: ZERO CHROMA, LLC, Sykesville, MD (US)

(72) Inventors: Brian E. LE GETTE, Severna Park, MD (US); David REEB, Sykesville, MD (US)

(73) Assignee: ZERO CHROMA, LLC, Sykesville, MD (US)

(21) Appl. No.: 15/145,530

(22) Filed: May 3, 2016

Related U.S. Application Data
(63) Continuation-in-part of application No. 13/887,036, filed on May 3, 2013, now Pat. No. 9,470,358.
Application No. 13/887,036 is a continuation-in-part of application No. 15/130,604, filed on Apr. 15, 2016.
Application No. 15/130,604 is a continuation of application No. 14/147,697, filed on Jan. 6, 2014, now Pat. No. 9,316,344.
Application No. 14/147,697 is a continuation-in-part of application No. 13/735,702, filed on Jan. 7, 2013, now Pat. No. 9,360,154.
Application No. 13/735,702 is a continuation-in-part of application No. 13/887,036, filed on May 3, 2013, now Pat. No. 9,470,358.
Application No. 13/887,036 is a continuation-in-part of application No. 14/627,848, filed on Feb. 20, 2015.
Application No. 14/627,848 is a continuation of application No. 13/345,345, filed on Jan. 6, 2012, now Pat. No. 8,960,634.
Application No. 13/345,345 is a continuation-in-part of application No. PCT/US11/31918, filed on Apr. 11, 2011.
Application No. PCT/US11/31918 is a continuation-in-part of application No. 12/758,377, filed on Apr. 12, 2010, now Pat. No. 8,382,059.
Application No. 12/758,377 is a continuation-in-part of application No. 12/556,182, filed on Sep. 9, 2009, now abandoned.
(60) Provisional application No. 61/191,454, filed on Sep. 9, 2008.

(51) Int. Cl. F16M 13/00; A45F 5/02; F16M 13/04; H05K 5/02; F16M 11/06

(52) U.S. Cl. CPC F16M 13/00; H05K 5/0234; F16M 13/005; F16M 11/06; F16M 13/04; A45F 5/02

(57) ABSTRACT

A support and/or mount apparatus for a mobile or portable electronic device is provided, and systems and methods thereof. The support and/or mount apparatus is configured to function as a support and/or a mount for the mobile or portable electronic device. The support and/or mount apparatus can support or otherwise have the mobile or portable electronic device mounted thereto at a first interconnection or interface and/or the support and/or mount apparatus itself can be mounted to another structure at a second interconnection or interface different from the first interconnection or interface.

### CROSS-REFERENCE TO RELATED APPLICATIONS

This application is a continuation-in-part of U.S. application Ser. No. 15/130,604, filed Apr. 15, 2016, which is a continuation of U.S. application Ser. No. 14/147,697, filed Jan. 6, 2014 (now U.S. Pat. No. 9,316,344), which is a continuation-in-part of U.S. application Ser. No. 13/735,702, filed Jan. 7, 2013, and a continuation-in-part of U.S. application Ser. No. 13/887,036, filed May 3, 2013. This application is also a continuation-in-part of U.S. application Ser. No. 13/887,036, filed May 3, 2013. This application is also a continuation-in-part of U.S. application Ser. No. 14/627,848, filed Feb. 20, 2015, which is continuation of U.S. application Ser. No. 13/345,345, filed Jan. 6, 2012 (now U.S. Pat. No. 8,960,634), which is a continuation-in-part of International App. No. PCT/US11/31918, filed Apr. 11, 2011, which is a continuation-in-part of U.S. application Ser. No. 12/758,377, filed Apr. 12, 2010 (now U.S. Pat. No. 8,382,059), which is a continuation-in-part of U.S. application Ser. No. 12/556,182, filed Sep. 9, 2009 (now abandoned). The entire content and disclosure of each of the foregoing applications is herein incorporated by reference.

### SUMMARY

Generally speaking, embodiments of the disclosed subject matter relate to mobile or portable electronic device support systems, apparatuses, and methods, particularly cases (including partial cases), mounts, stands, biosensors, and straps. In one or more embodiments, a support and/or mount apparatus for a mobile or portable electronic device is provided.

According to one or more embodiments of the disclosed subject matter, a support system is provided. The support system is configured to serve as one or both of a mount connection and a surface support for a mobile electronic device. The support system can comprise: a body configured to be coupled to the mobile electronic device, one of directly, indirectly, and each of directly and indirectly, separately, at a first interface; and a base structure rotatably connected to the body configured to be coupled to a separable mounting structure for the mount connection of the support system, different from the mobile electronic device, at a second interface different from the first interface.

One or more embodiments of the disclosed subject matter also include an apparatus configured to serve as a mount connection and a surface support for a portable electronic device with a display screen. The apparatus can comprise: a body configured to be selectively and individually coupled to the portable electronic device and to a case over the portable electronic device, by snapping over and/or sliding onto, directly and indirectly, only a first set of opposite sides of the portable electronic device and not a second set of opposite sides of the portable electronic device; and a base structure rotatably connected to the body configured to be coupled to a separable mounting structure, different from the portable electronic device, at a second interface different from the first interface. The portable electronic device, the apparatus, and the mounting structure are distinct components, the portable electronic device is separable from the body of the apparatus when the base structure is coupled to the mounting structure, the base structure of the apparatus is separable from the mounting structure when the portable electronic device is coupled to the body, either directly or indirectly, and the portable electronic device portable electronic device is separable from the body of the apparatus and the base structure of the apparatus is separable from the mounting structure.

Other features and aspects of this disclosure will be apparent from the following description and the accompanying drawings.

### BRIEF DESCRIPTION OF THE DRAWINGS

The accompanying drawings, which are incorporated in and constitute a part of the specification, are illustrative of one or more embodiments and, together with the description, explain the embodiments. The accompanying drawings have not necessarily been drawn to scale. Further, any values or dimensions in the accompanying drawings are for illustration purposes only and may or may not represent actual or preferred values or dimensions. Where applicable, some or all select features may not be illustrated to assist in the description and understanding of underlying features.

FIG. 1 is a front, side perspective view of a portion of a body sensing system according to one or more embodiments of the disclosed subject matter.

FIG. 2 is a front elevational view of the portion of the body sensing system of FIG. 1.

FIG. 3 is a back elevational view of the portion of the body sensing system of FIG. 1.

FIG. 4 a left side elevational view of the portion of the body sensing system of FIG. 1.

FIG. 5 is a front perspective view of the portion of the body sensing system of FIG. 1 with a connection mechanism according to one or more embodiments of the disclosed subject matter.

FIG. 6 is a back perspective view of the portion of the body sensing system of FIG. 1 with the connection mechanism of FIG. 5.

FIG. 7 is a front, side perspective view of a portion of a body sensing system according to one or more embodiments of the disclosed subject matter, with a removable sensor unit.

FIG. 8 is a front, side perspective view of the portion of the body sensing system of FIG. 7 with the removable sensor unit removed from a body of the portion of the body sensing system.

FIG. 9 is a front perspective view of a support and/or mount apparatus according to one or more embodiments of the disclosed subject matter.

FIG. 10 is a front elevational view of the support and/or mount apparatus of FIG. 9.

FIG. 11 is a cut-away perspective view of the support and/or mount apparatus of FIG. 9.

FIG. 12 is a side elevational view of the support and/or mount apparatus of FIG. 9 (the left and right sides can be mirror images).

FIG. 13 is a bottom elevational view of the support and/or mount apparatus of FIG. 9.

FIG. 14 is a top elevational view of the support and/or mount apparatus of FIG. 9.

FIG. 15 is a back elevational view of the support and/or mount apparatus of FIG. 9.

FIG. 16 is a back perspective view of the support and/or mount apparatus of FIG. 9.

FIG. 17 is a front perspective view of a support and/or mount apparatus comprised of a body and a removable adaptor and base structure with a stand, where the adaptor and base structure are shown removed from the body, according to one or more embodiments of the disclosed subject matter.

FIG. 18 is a bottom elevational view of the support and/or mount apparatus of FIG. 17 with the removable adaptor and base structure shown removed from the body.

FIG. 19 is a front perspective view of the support and/or mount apparatus of FIG. 17 with the removable adaptor and base structure shown coupled to the body.

FIG. 20 is a cut-away perspective view of the support and/or mount apparatus of FIG. 19.

FIG. 21 is a front elevational view of the support and/or mount apparatus of FIG. 19.

FIG. 22 is a bottom elevational view of the support and/or mount apparatus of FIG. 19.

FIG. 23 is a top elevational view of the support and/or mount apparatus of FIG. 19.

FIG. 24 is a sectional view looking top to bottom or vice versa of the support and/or mount apparatus of FIG. 19.

FIG. 25 is a side elevational view of the support and/or mount apparatus of FIG. 19 (the left and right sides can be mirror images).

FIG. 26 is a back elevational view of the support and/or mount apparatus of FIG. 19.

FIG. 27 is an exploded view of a support and/or mount apparatus according to one or more embodiments of the disclosed subject matter.

FIG. 28 is another exploded view of the support and/or mount apparatus of FIG. 27.

FIG. 29 is a front perspective view of the support and/or mount apparatus of FIG. 9 positioned to be indirectly coupled to a portable or mobile electronic device.

FIG. 30 is a front perspective view of the support and/or mount apparatus of FIG. 9 indirectly coupled to a portable or mobile electronic device.

FIG. 31 is a front elevational view of the indirect coupling according to FIG. 30.

FIG. 32 is a left side elevational view of the indirect coupling according to FIG. 30.

FIG. 33 is a back perspective view of the indirect coupling according to FIG. 30.

FIG. 34 is another front perspective view of the indirect coupling according to FIG. 30.

FIG. 35 is a bottom elevational view of the indirect coupling according to FIG. 30.

FIG. 36 is a front, bottom perspective view of the support and/or mount apparatus of FIG. 9 positioned to be snapped or snap coupled to a groove in a case to hold a portable or mobile electronic device.

FIG. 37 is front, bottom perspective view of the support and/or mount apparatus of FIG. 9 snapped or snap coupled groove, smaller than the groove of FIG. 36, in a case to hold a portable or mobile electronic device.

FIG. 38 front, bottom perspective view of the support and/or mount apparatus of FIG. 9 positioned to be slide on or slide-coupled to the groove of the case of FIG. 36.

FIG. 39 is a front perspective view of the support and/or mount apparatus according to one or more embodiments of the disclosed subject matter indirectly coupled to a portable or mobile electronic device.

FIG. 40 is a front, bottom perspective view of the indirect coupling according to FIG. 39.

FIG. 41 is a back perspective view of the indirect coupling according to FIG. 39.

FIG. 42 is a front perspective view of the support and/or mount apparatus according to one or more embodiments of the disclosed subject matter directly coupled to a portable or mobile electronic device.

FIG. 43 is a back perspective view of the direct coupling according to FIG. 40.

FIG. 44 is a perspective view of a support and/or mount apparatus according to one or more embodiments of the disclosed subject matter.

FIG. 45 is a cross-sectional perspective view of the support and/or mount apparatus of FIG. 44.

FIG. 46 is a front perspective view of an example of a mounting structure according to one or more embodiments of the disclosed subject matter.

FIG. 47 is left side elevational view of the mounting structure of FIG. 46.

FIG. 48 is a back elevational view of the mounting structure of FIG. 46.

FIG. 49 is a bottom elevational view of the mounting structure of FIG. 46.

FIG. 50 is a top elevational view of the mounting structure of FIG. 46.

FIG. 51 is a front perspective exploded view of the mounting structure of FIG. 46.

### DETAILED DESCRIPTION

The description set forth below in connection with the appended drawings is intended as a description of various embodiments of the described subject matter and is not necessarily intended to represent the only embodiment(s). In certain instances, the description includes specific details for the purpose of providing an understanding of the described subject matter. However, it will be apparent to those skilled in the art that embodiments may be practiced without these specific details. In some instances, well-known structures and components may be shown in block diagram form in order to avoid obscuring the concepts of the described subject matter. Wherever possible, the same reference numbers will be used throughout the drawings to refer to the same or the like parts.

Any reference in the specification to “one embodiment” or “an embodiment” means that a particular feature, structure, characteristic, operation, or function described in connection with an embodiment is included in at least one embodiment. Thus, any appearance of the phrases “in one embodiment” or “in an embodiment” in the specification is not necessarily referring to the same embodiment. Further, the particular features, structures, characteristics, operations, or functions may be combined in any suitable manner in one or more embodiments, and it is intended that embodiments of the described subject matter can and do cover modifications and variations of the described embodiments.

It must also be noted that, as used in the specification, appended claims and abstract, the singular forms “a,” “an,” and “the” include plural referents unless the context clearly dictates otherwise. That is, unless clearly specified otherwise, as used herein the words “a” and “an” and the like carry the meaning of “one or more.” Additionally, it is to be understood that terms such as “left,” “right,” “top,” “bottom,” “front,” “rear,” “side,” “height,” “length,” “width,” “upper,” “lower,” “interior,” “exterior,” “inner,” “outer,” and the like that may be used herein, merely describe points of reference and do not necessarily limit embodiments of the described subject matter to any particular orientation or configuration. Furthermore, terms such as “first,” “second,” “third,” etc. merely identify one of a number of portions, components, points of reference, operations and/or functions as described herein, and likewise do not necessarily limit embodiments of the described subject matter to any particular configuration or orientation.

As noted above, embodiments of the disclosed subject matter involve electronic device support systems, apparatuses, and methods. As used herein, an electronic device can be a portable or mobile electronic device, including, but limited to, a smartphone, a tablet, a Personal Digital Assistant (PDA), a display monitor, a relatively small television (e.g., 7″ screen), a laptop or portion thereof (e.g., monitor or keyboard), a keyboard, or a medical monitoring device user interface.

Generally speaking, one or more embodiments of the disclosed subject matter relate to a support and/or mount apparatus for a mobile or portable electronic device configured to function as a support and/or a mount for the mobile or portable electronic device. The support and/or mount apparatus can be substantially permanently, built into, integral, or formed one piece with the mobile or portable electronic device. Alternatively, the support and/or mount apparatus can be removably coupled to the mobile or portable electronic device.

For example, the support and/or mount apparatus can (1) support or otherwise have the mobile or portable electronic device mounted thereto (e.g., removably) at a first interconnection or interface and/or (2) the support and/or mount apparatus itself can be mounted to another structure at a second interconnection or interface different from the first interconnection or interface. Optionally, in one or more embodiments of the disclosed subject matter, the support and/or mount apparatus provides the sole means by which a mobile electronic device mounted thereto can one or more of rotate and change angles when the support and/or mount apparatus is removably mounted to another structure at the second interconnection or interface. That is, the support and/or mount apparatus can be configured to provide the means by which the mobile electronic device mounted thereto can one or more of rotate and change angles and not the another structure to which the support and/or mount apparatus is mounted. Thus, the mechanism by which the mobile electronic device can one or more of rotate and change angles can “stay with” the mobile electronic device when the support and/or mount apparatus is dismounted or decoupled from the another structure.

Optionally, the support and/or mount apparatus is removably coupled to the mobile electronic device, directly and indirectly, for instance, to a removable case removably coupled to the mobile electronic device. That is, in one or more embodiments of the disclosed subject matter, the support and/or mount apparatus can be removably coupled directly to the mobile electronic device when a removable case is not coupled to the electronic device (or does not cover the portion of the mobile electronic device to which the support and/or mount apparatus is directly coupled), and can also be coupled to the removable case when the removable case is coupled to the mobile electronic device and the support and/or mount apparatus is coupled directly to the removable case.

In one or more embodiments of the disclosed subject matter, the support and/or mount apparatus can be snapped on, slid on, elastically wrapped around, and/or memory formed to or around the mobile electronic device, directly and indirectly, for instance, via a case removably coupled to the mobile electronic device.

Optionally, the support and/or mount apparatus includes a stand, which can rotate about a first axis between a fully retracted position to a fully extended position. Optionally, the stand can also rotate about a second axis in a plane perpendicular to a plane of the first axis, for instance, to provide portrait and landscape orientations for the mobile electronic device and/or the removable case with or without the removable case being coupled to the mobile electronic device. For example, the stand can rotate about a first axis at which the stand is rotatably coupled to a base structure of the support and/or mount apparatus. Further, the base structure itself can be rotatably coupled to a body of the support and/or mount apparatus, such that the base structure, and consequently the stand, can rotate about a second axis in a plane perpendicular to a plane of the first axis.

The stand, and optionally the base structure of the support and/or mount apparatus to which the stand may be rotatably coupled about the first axis, can be substantially fixedly coupled to the body of the support and/or mount apparatus. In this regard, fixedly coupled can mean that the two components are not intended to be separated, but the stand can rotate about the first axis and optionally about the second axis in a situation where the base structure is rotatable about the second axis.

Alternatively, the stand, and optionally the base structure of the support and/or mount apparatus to which the stand may be rotatably coupled about the first axis, can be removable from the body of the support and/or mount apparatus. Further, optionally, in one or more embodiments of the disclosed subject matter, the stand, and optionally the base structure of the support and/or mount apparatus to which the stand may be rotatably coupled about the first axis, can be interchanged with another stand (and optionally the base structure), for instance, of a same size, but different configuration, such as a stand having an elastic strap, such according to the disclose of U.S. application Ser. No. 15/130,604 and U.S. application Ser. No. 14/147,697 (now U.S. Pat. No. 9,316,344), the entire content and disclosure of which is herein incorporated by reference, as noted above.

Optionally, the base structure (and stand) can be interchanged with a base structure of another size, for instance, smaller in diameter or circumference from a plan view, using at least one adaptor configured to fit into a receptacle of the body of the support and/or mount apparatus configured to removably hold the adaptor and separately the base structure with larger diameter or circumference (i.e., the “initial” base structure). Likewise, the base structure (and stand) can remain the same and the body of the support and/or mount apparatus can be interchanged with another body of the support and/or mount apparatus. For example, a body of a support and/or mount apparatus with a relatively large diameter or circumference to accommodate the base structure can be interchanged with the body of the “initial” support and/or mount apparatus, such that the “initial” base structure can be held, using at least one adaptor configured to fit into a receptacle of the body of the support and/or mount apparatus with the relatively larger diameter or circumference. Thus, one base structure and stand can be used with a variety of different support and/or mount apparatus bodies. Likewise, one support and/or mount apparatus body can be used with a variety of different base structures and stands.

In one or more embodiments, circuitry including a sensor or sensors, can be provided in or as part of a base structure configured to contact a part of a wearer's body to sense one or more physiological parameters or characteristics of the wearer. Signals from the sensor or sensors regarding the sensed physiological parameters or characteristics can be processed by the circuitry to form physiological data representative of the sensed physiological parameters or characteristics and sent to a mobile or portable electronic device relatively close to the circuitry, or, additionally or alternatively, the signals from the sensor or sensors regarding the sensed physiological parameters or characteristics can be sent to the mobile electronic device where the signals can be further processed form physiological data representative of the sensed physiological parameters or characteristics and output, for instance, using a display and/or speaker. Optionally, the signals from the sensor or sensors and/or the physiological data can be sent to the mobile electronic device. Further, the base structure may serve as a mount to which the mobile electronic device can be removably mounted, either directly, for example, by way of a built-in support and/or mount apparatus (e.g., stand) of the mobile electronic device, or indirectly, for instance, by way a removable support and/or mount apparatus or case (e.g., having a built-in stand) configured to engage a portion of the mobile electronic device or an adaptor between the removable support and/or mount apparatus or case and the mobile electronic device.

More specifically, in one or more embodiments of the disclosed subject matter, a base structure can be configured to contact a part of a wearer's body (or other clothing in certain instances based on the configuration of the clothing) and can have circuitry including a sensor or sensors to sense one or more physiological parameters or characteristics of the wearer (including biometric parameters or characteristics), such as heart rate, blood oxygen level, body temperature, pH, and other parameters or characteristics of the wearer, such as speed, acceleration, direction of movement, location, etc. using corresponding gyroscopes, global positioning circuitry, etc. Signals from the one or more sensors can be processed using the circuitry to form data representative of the sensed parameters or characteristics and sent to a mobile electronic device relatively close to the circuitry where such data can be output, for instance, using a display and/or speaker of the mobile electronic device.

Optionally, the signals from the sensor or sensors and/or the data can be sent wirelessly to the mobile electronic device, for instance, using one or more short-range wireless technologies and communication protocols, a wireless communication protocol, such as near-field communication (NFC), Bluetooth®, or short-link communication, etc. Additionally or alternatively, the base structure can form a wired connection with the mobile electronic device using built-in leads of the base structure and/or mobile electric device (and optionally a case of the mobile electric device).

The base structure may be held on or against a particular part of the wearer's body, for instance, the forearm, upper arm, upper leg, torso, waist, or head, by a connection mechanism, which can be a strap, band, or belt, for example, and may be adjustable and/or elastic. Optionally, the connection mechanism can be removable from the base structure and replaced with another connection mechanism of different type or size, for instance.

In one or more embodiments, the base structure may serve as a mount to which the mobile electronic device can be removably mounted, either directly, for example, by way of a support and/or mount apparatus (e.g., a built-in stand) of the mobile electronic device, or indirectly, for instance, by way a removable support and/or mount apparatus or case (e.g., with a built-in stand) configured to engage a portion of the mobile electronic device or an intermediate component between the removable support and/or mount apparatus and the mobile electronic device. Alternatively, the mobile electronic device may be affixed to the connection mechanism discussed above. For example, the mobile electronic device may be clipped to a strap that holds the base structure having the circuitry to sense one or more physiological parameters or characteristics of the wearer on or against the particular part of the wearer's body.

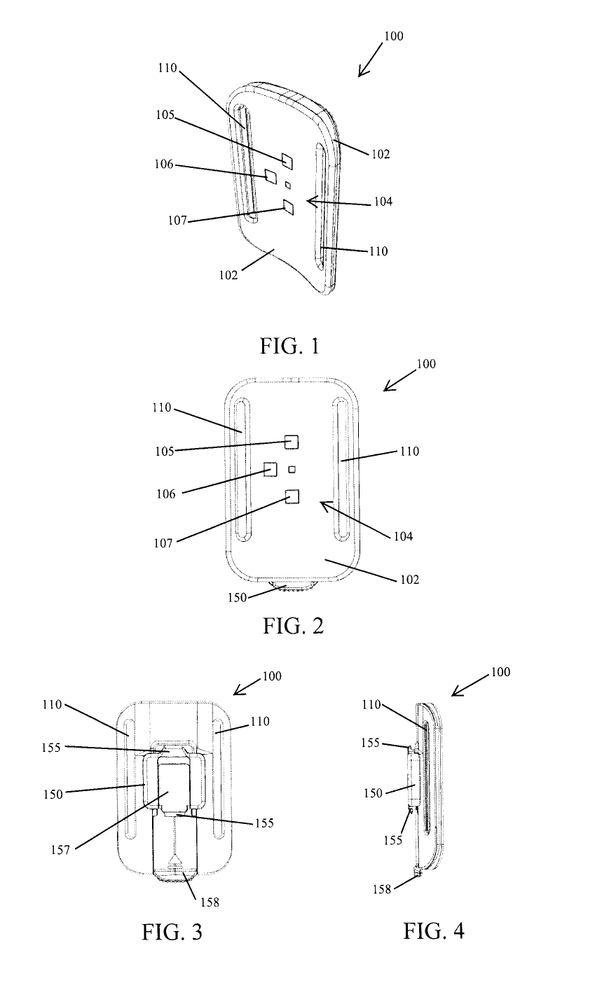

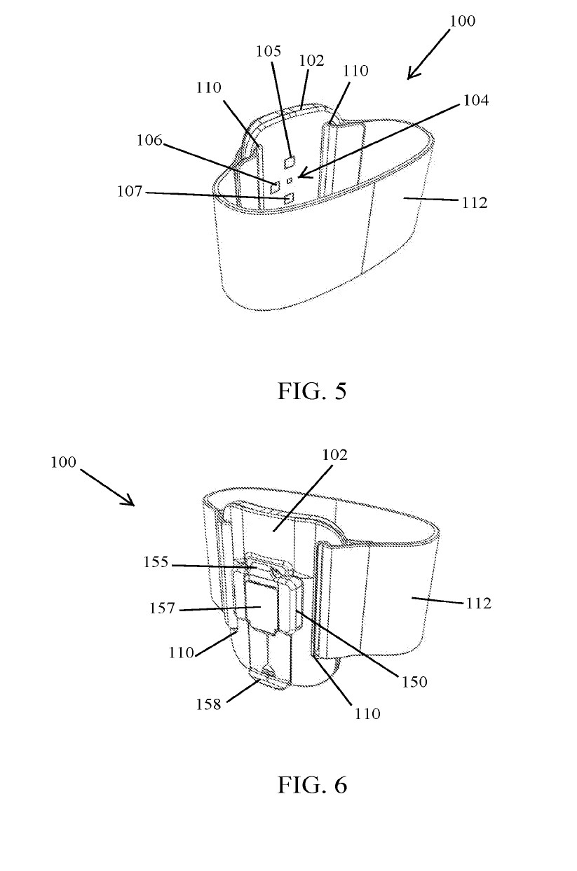

FIGS. 1-4 show various views of a portion of a body sensing system 100 according to one or more embodiments of the disclosed subject matter, and FIGS. 5 and 6 show the portion of the body sensing system 100 of FIG. 1 with a connection mechanism according to one or more embodiments of the disclosed subject matter.

In particular, FIGS. 1-6 show a base structure 102, of body sensing system 100, comprised of circuitry 104, which can include one or more sensors 105, 106, 107. The circuitry can also include a processor or processing circuitry and a transmitter or transceiver (not expressly illustrated). Generally speaking, the base structure 102 can be configured to be placed on or against a part of a wearer's body such that the sensors can sense or detect a physiological parameter or characteristic of the wearer or different physiological parameters or characteristics of the wearer. The circuitry can also sense or detect other parameters or characteristics of the wearer, such as speed, acceleration, direction of movement, location, etc. using corresponding gyroscopes, global positioning circuitry, etc. of the circuitry.

The circuitry 104, which in the embodiment of FIGS. 1-6 is embedded in, part of, or non-removable from the base structure 102, can sense and process physiological parameter(s) or characteristic(s) of the wearer when or while the base structure 102 is placed on or against the part of the wearer's body. Further, the circuitry 104 can transmit, using a transmitter, signals from the sensors or physiological data representative of the sensed physiological parameters or characteristics and other parameters or characteristics of the wearer to a mobile electronic device relatively close to the base structure 102, such as fixed directly or indirectly to the base structure 102 or another portion of the body sensing system 100, such as a connection mechanism 112 (shown in FIGS. 5 and 6). The circuitry 104 can interact with an application running on the mobile electronic device and vice versa. For example, control of the application running on the mobile electronic device can be based on physical movements by the wearer as detected by the circuitry 104 and/or the mobile electronic device.

Optionally, all of the sensors 105, 106, 107 may be activated to sense physiological parameter(s) or characteristic(s) of the wearer, for instance, based on sensor activation by the wearer using a user interface of the base structure 102 and/or a mobile electronic device relatively close to the base structure 102, such as fixed directly or indirectly to the base structure 102 or another portion of the body sensing system 100. Alternatively, only a portion of the sensors 105, 106, 107 may be activated to sense physiological parameter(s) or characteristic(s) of the wearer.

The base structure 102 can have connector interfaces 110 to connect to a connection mechanism 112, which can hold the base structure 102 on or against a particular part of the wearer's body. FIGS. 5 and 6, for instance, illustrate a strap 112 as the connection mechanism 112 connected to the connector ports 110 and configured to be provided around a particular part of the wearer's body to hold the base structure 102 on or against the part of the wearer's body.

Further, the base structure 102 can have a back side with a mount or mounting member 150, for instance, to removably mount a mobile electronic device, directly thereto or indirectly thereto, through a support and/or mount apparatus or case configured to engage the mobile electronic device (or the case when both a support and/or mount apparatus and case are implemented). Optionally, at least the mobile electronic device is rotatable, relative to the mounting member 150, in a same plane and/or about different planes when connected to the mounting member 150. As noted above, support and/or mount apparatuses according to various embodiments of the disclosed subject matter can be configured to provide for such rotation(s) and, in one or more embodiments, may be the sole means by which such rotation(s) is implemented.

Such mounting can be performed in any suitable way. For instance, the mobile electronic device (or case/holder of the mobile electronic device) can be snap fit or slid to be removably mounted to the mounting member 150. Examples of mobile electronic devices and cases connectable to base structures according to embodiments of the disclosed subject matter, such as base structure 102, include those according to the present disclose as well as those according to the disclosure of U.S. application Ser. No. 13/887,036, U.S. application Ser. No. 15/130,604, U.S. application Ser. No. 14/147,697, U.S. application Ser. No. 13/735,702, U.S. application Ser. No. 14/627,848, U.S. application Ser. No. 13/345,345, International App. No. PCT/US11/31918, U.S. application Ser. No. 12/758,377, and U.S. application Ser. No. 12/556,182, the entire content and disclosure of each of which is herein incorporated by reference, as noted above.

Additionally, optionally, the mounting member 150 can operate according to the disclosure of U.S. application Ser. No. 13/887,036, which is herein incorporated by reference in its entirety.

In particular, the mounting member 150 and mobile electronic device (or case/holder of the mobile electronic device) can be coupled together via an engagement/disengagement member 155, which can include flanges, a moveable member 157, and sliding member 158 coupled to moveable member 157. Optionally, moveable member 157 and sliding member 158 can be formed as one piece or they may be separate pieces coupled together. Generally speaking, engagement/disengagement member 155 can be connected to a receptacle of a mobile electronic device or support and/or mount apparatus or case configured to engage the mobile electronic device, for instance, according to the disclosure of U.S. application Ser. No. 13/887,036 or as described herein. Optionally, the moveable member 157 may be held in the engaged or locked position by a locking device, such as a snap or ridge to mate in locking fashion to corresponding slot. Additionally, a side of the engagement/disengagement member 155 perpendicular to the sides of the engagement/disengagement member 155 having the flanges may abut a fastening portion to provide a more stable and reliable fit and lock.

Moveable member 157 can be moved in correspondence with movement of sliding member 158. That is, a user may push sliding member 158 (upward in the case of FIG. 3, for example) to move the moveable member 157 in the same direction, for example, so the engagement/disengagement member 155 can be inserted into a receptacle of a mobile electronic device (or mount apparatus or case of the mobile electronic device). The sliding member 158 can be moved to an engagement position to make the moveable member 157 also move in the same direction in order to engage and lock the engagement/disengagement member 155 to the mobile electronic device (or case/holder of the mobile electronic device). In embodiments, a biasing member (not expressly shown) may bias and push the sliding member 158 and thus the moveable member 157 to the engagement position. That is, the engagement position may be the “home” position for the sliding member 158 and the moveable member 157.

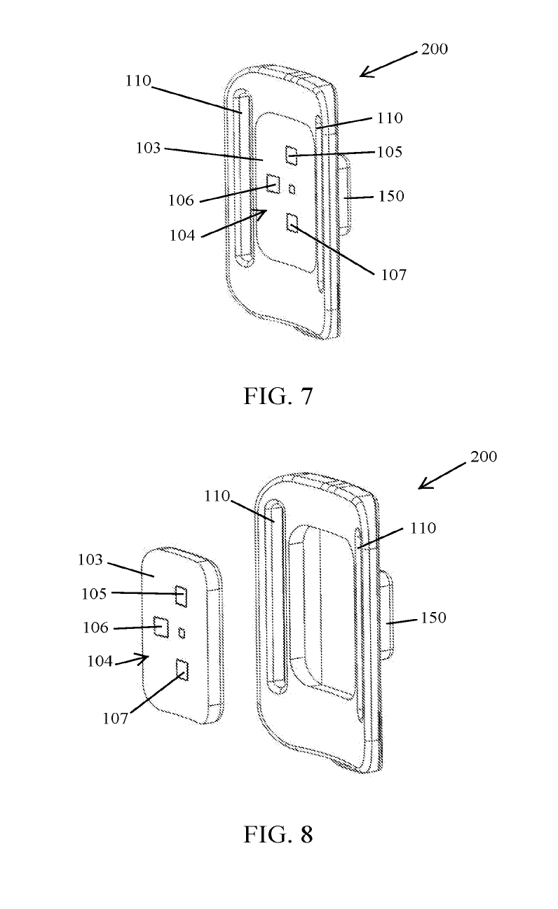

As noted above, the circuitry 104 may be embedded or part of (i.e., not removable from) the base structure 102. However, alternatively, some or all of the circuitry 104 may be removable from the base structure 102. For example, FIGS. 7 and 8 illustrate a body sensing system 200 according to one or more embodiments of the disclosed subject matter, where circuitry 104 is provided in a removable sensor unit 103, which can be inserted and removed from a receptacle in the base structure 102. Thus, different sensor units 103 may be switched out for a particular application, battery charge, software update, replacement, etc. Additionally, though not expressly illustrated in FIGS. 7 and 8, an adaptor may be removably provided in the receptacle so different sized sensor units 103 can be provided to the base structure 102.

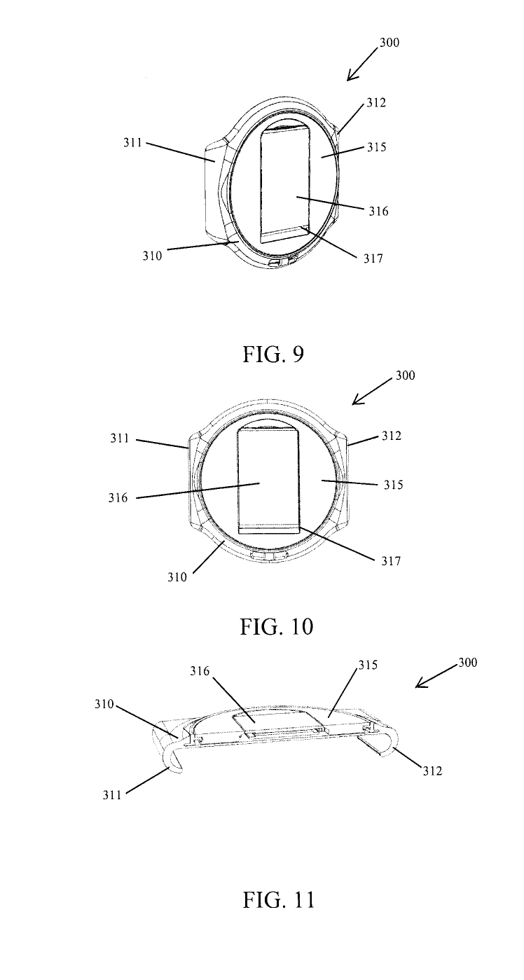

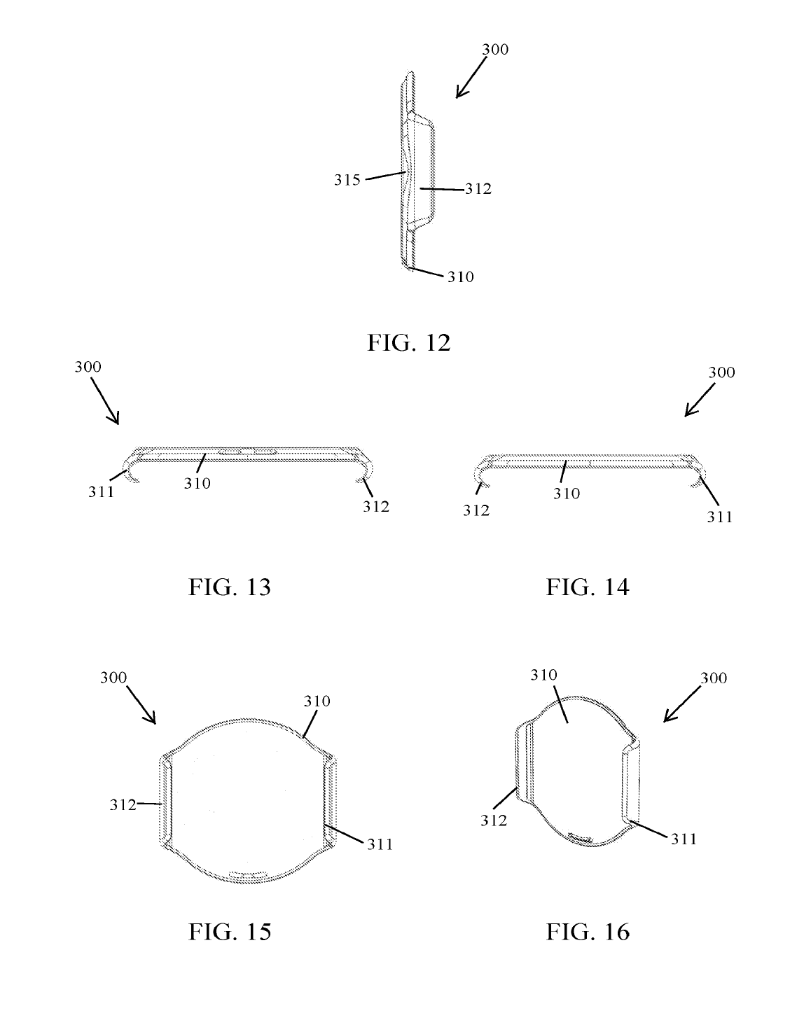

Turning now to FIGS. 9-16, these figures illustrate a non-limiting example of a support and/or mount apparatus 300 according to one or more embodiments of the disclosed subject matter. Generally speaking, the support and/or mount apparatus 300 can (1) support or otherwise have a mobile or portable electronic device mounted thereto (e.g., removably) at a first interconnection or interface 350 on the back side of the support and/or mount apparatus 300. The support and/or mount apparatus 300 can itself be mounted to another structure at a second interconnection or interface different from the first interconnection or interface, for instance, to the mounting or mounting member 150 of the base structure 102 discussed above. Also, the support and/or mount apparatus 300 can be removably coupled (i) directly, (ii) indirectly, or (iii) separately directly and indirectly to a portable or mobile electronic device as described herein. Support and/or mount apparatus 300 can be snapped and/or slid on to the mobile electronic device or a case or other intermediate component provided between the mobile electronic device and the support and/or mount apparatus 300.

The support and/or mount apparatus 300 can include a body 310 and a base structure 315 coupled to the body 310. Optionally, the base structure 315 can have a stand 316 configured to rotate about a first axis 317, from a fully retracted position as illustrated in FIGS. 9-14, to a fully extended position, which may be more than ninety degrees from the fully retracted position. Further, optionally, the stand 316 can be fixedly held at any position at or between the fully retracted position and the fully extended position. Optionally, the base structure 315 can rotate relative to the body 310, about a second axis in a plane perpendicular to a plane of the first axis 317. In one or more embodiments of the disclosed subject matter the base structure 315 and interface with the body 310 can be based on, similar to or the same as that described in U.S. application Ser. No. 13/887,036, previously incorporated herein by reference in its entirety.

The body 310 can include engagement members 311, 312 configured to engage a portable electronic device and/or a case or intermediate component between the body 310 and the portable electronic device. The engagement members 311, 312 can wrap around respective opposite sides of the portable electronic device and/or the case or intermediate component between the body 310 and the portable electronic device. Additionally or alternatively, the engagement members 311, 312 can be slid on or slidably coupled to, for instance, from one or both ends, the portable electronic device and/or the case or intermediate component between the body 310 and the portable electronic device. Additionally or alternatively, the engagement members 311, 312 can be caused to flex or bend to receive the portable electronic device and/or the case or intermediate component between the body 310 and the portable electronic device and then wrapped around and/or shape formed to at least respective opposite sides of the portable electronic device and/or the case or intermediate component between the body 310 and the portable electronic device.

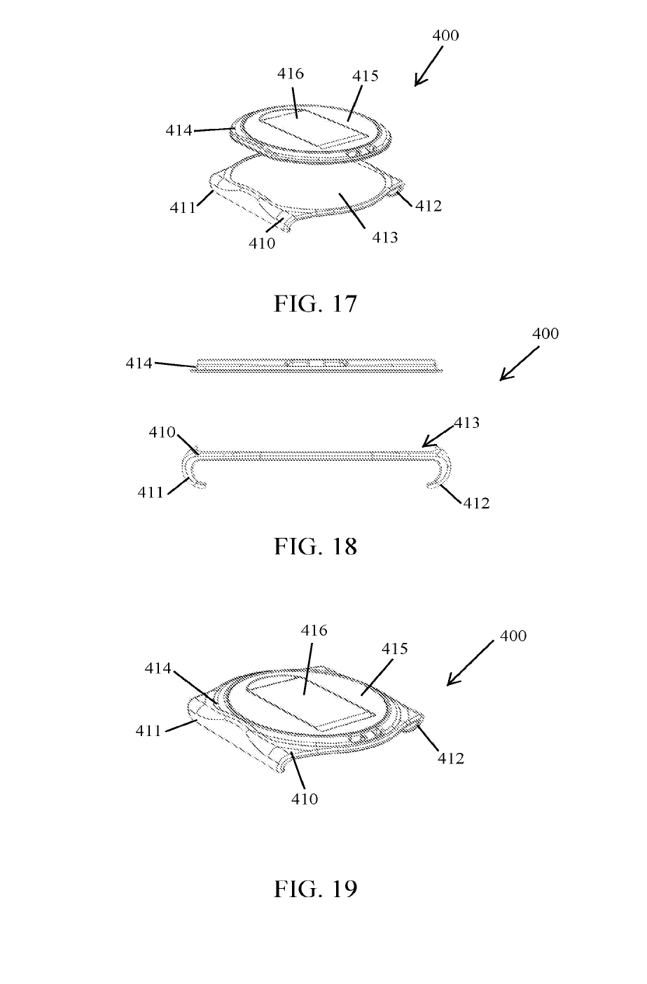

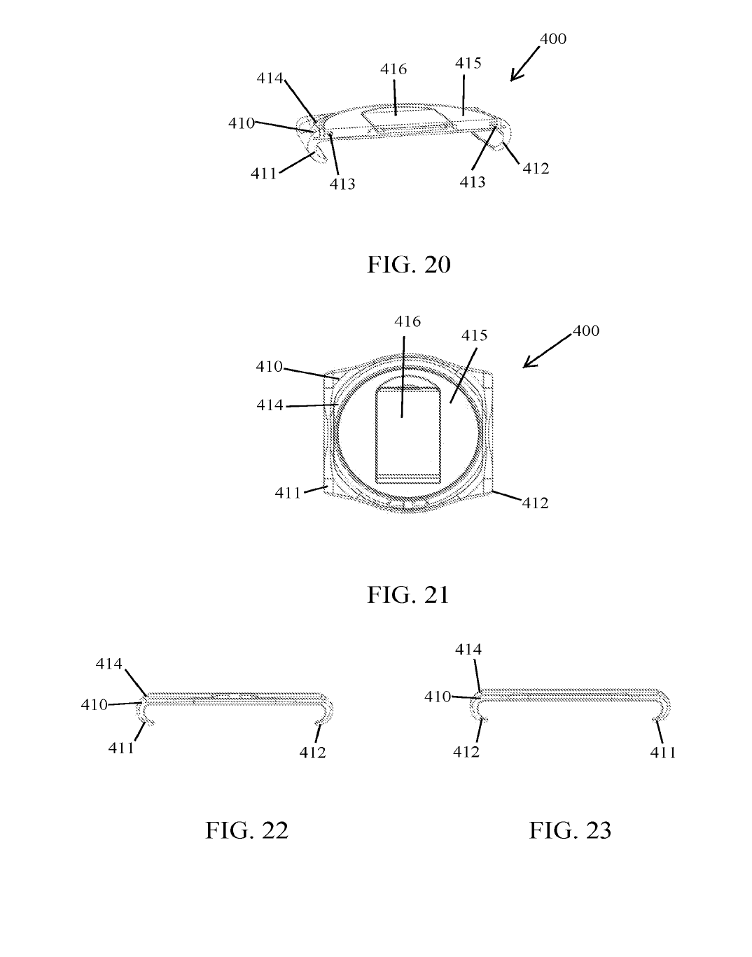

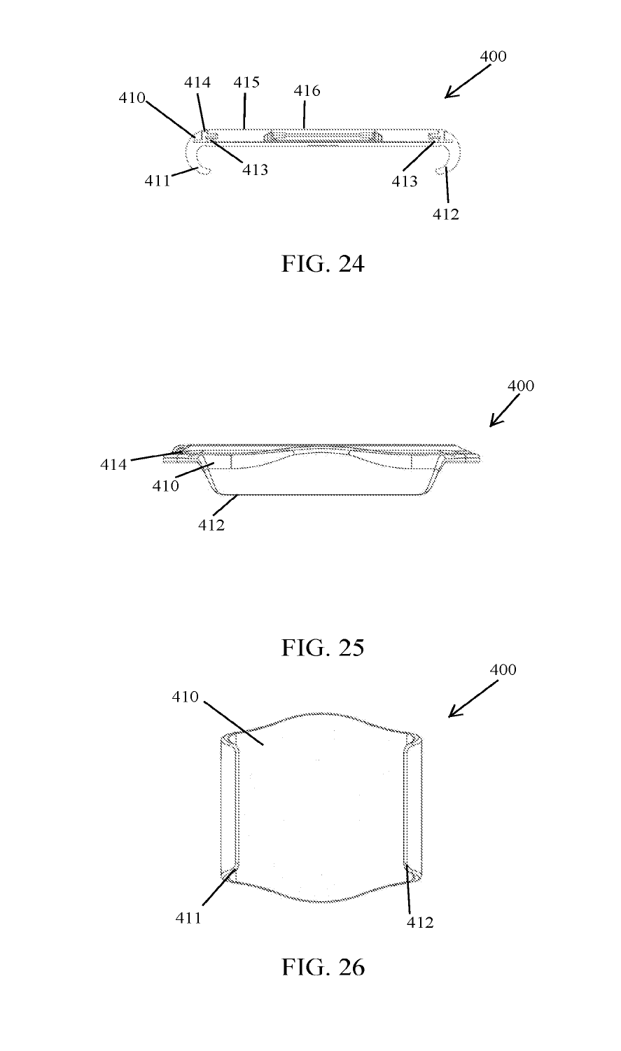

Optionally, the base structure 315 can be substantially permanently coupled to the body 310 (though some embodiments of which still all for rotation of the base structure 315 relative to the body 310 about the second axis). Alternatively, as illustrated in FIGS. 17-26, for instance, one or more embodiments of the disclosed subject matter can include a support and/or mount apparatus 400 having a body 410 removably coupled to a base structure 415 having engagement members 411, 412, which may include a stand 416, by way of an adaptor 414, which itself may be removably coupled to base structure 415 (and of course the body 410).

FIGS. 17-26 illustrate the adaptor 412 being received by a receptacle 413 of the body 410 from a front side of the support and/or mount apparatus 400, although the adaptor 414 may additionally or alternatively be received in the receptacle 413 from the back side of the support and/or mount apparatus 400 or sandwiched between front and back components that would comprise receptacle 413, according to various embodiments of the disclosed subject matter.

The adaptor 414 may be snapped into the receptacle 413, for instance. Alternatively, the adaptor 414 may be merely arranged to contact the body 410 so as to prevent rotation of the adaptor 414 about the second axis (but optionally allow rotation of the base structure 415 about the second axis) and held in place when the support and/or mount apparatus 400 is removably coupled to the portable electronic device and/or the case or intermediate component between the adaptor 414 and the portable electronic device. Thus, in one or more embodiments of the disclosed subject matter, base structures 415 of different sizes and configurations, such as different configurations that rotate or do not rotate about the second axis and configurations with different stands, can be switched out from the body 410 by using an adaptor 414 that can couple to the body 410 and also the particular base structure or structures. Likewise, bodies 410 of different sizes and configurations can be switched out from the base structure 415 using an adaptor 414 that can couple to the base structure 415 and the particular body or bodies 410.

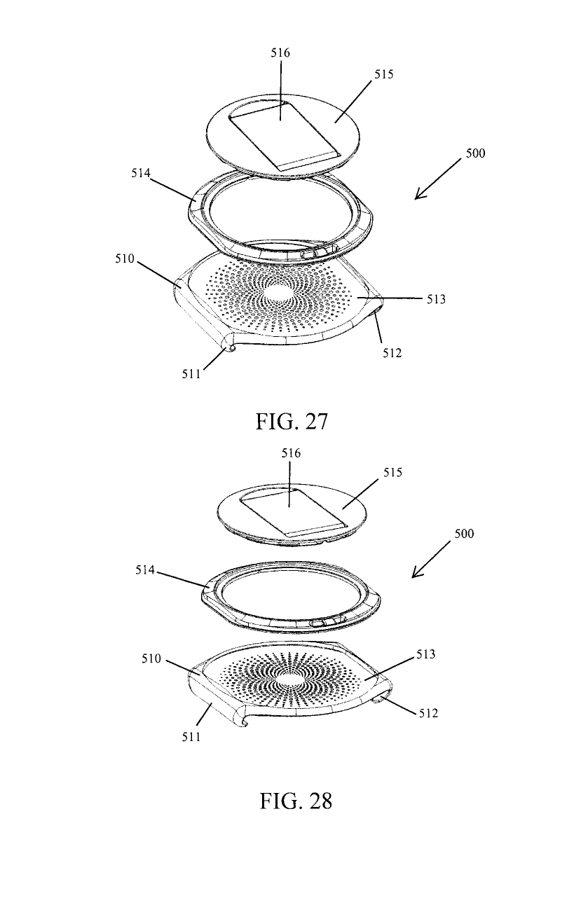

FIGS. 27 and 28 are exploded views of a support and/or mount apparatus 500 having a body 510 removably coupled to a base structure 515 having engagement members 511, 512, which may include a stand 516, by way of an adaptor 514, which itself may be removably coupled to base structure 415 (and of course the body 410), according to one or more embodiments of the disclosed subject matter.

Notably, adaptor 514 can be received by a receptacle 513 of the body 510 from a front side of the support and/or mount apparatus 500. In FIGS. 27 and 28, the receptacle 513 has a bottom surface. Thus, in these particular illustrations the adaptor 514 can only be received by receptacle 513 from the front side of the support and/or mount apparatus 500. Of course, alternatively, the receptacle 513 may not have a bottom surface as illustrated, and the adaptor 514 can be received by the receptacle 513 only from the back side of the support and/or mount apparatus 500, from the front and back sides of the support and/or mount apparatus 500, or sandwiched between front and back components that would comprise receptacle 513.

The adaptor 514 may be snapped into the receptacle 513, for instance. Alternatively, the adaptor 514 may be merely arranged to contact the body 510 so as to prevent rotation of the adaptor 514 about the second axis (but optionally allow rotation of the base structure 515 about the second axis) and held in place when the support and/or mount apparatus 500 is removably coupled to the portable electronic device and/or the case or intermediate component between the adaptor 514 and the portable electronic device. Thus, in one or more embodiments of the disclosed subject matter, base structures 515 of different sizes and configurations, such as different configurations that rotate or do not rotate about the second axis and configurations with different stands, can be switched out from the body 510 by using an adaptor 514 that can couple to the body 510 and also the particular base structure or structures. Likewise, bodies 510 of different sizes and configurations can be switched out from the base structure 515 using an adaptor 514 that can couple to the base structure 515 and the particular body or bodies 510.

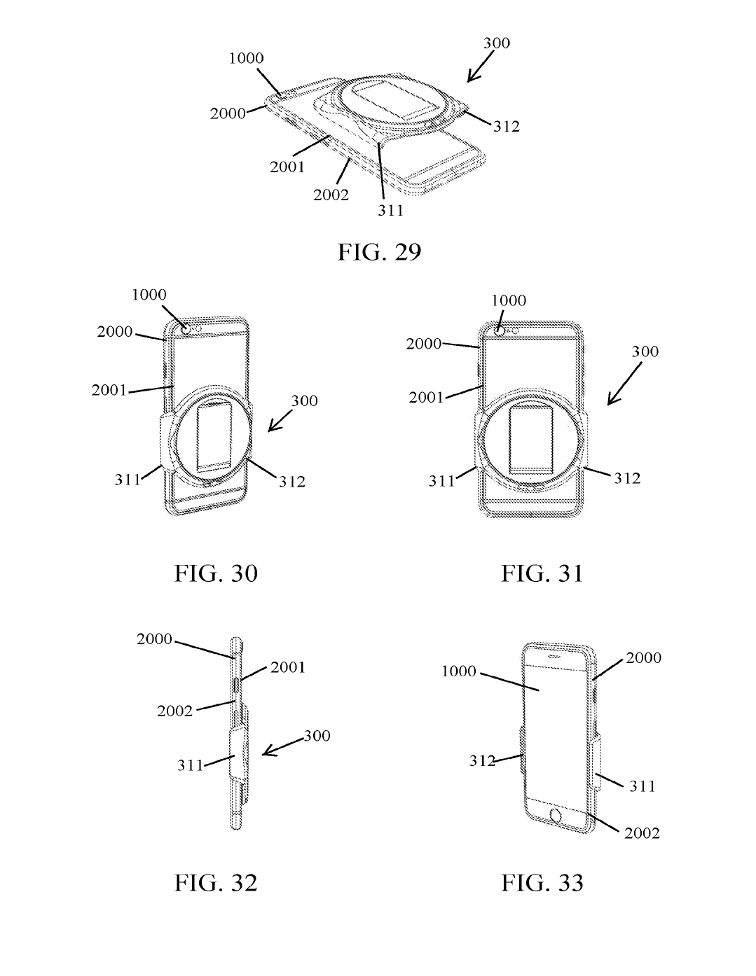

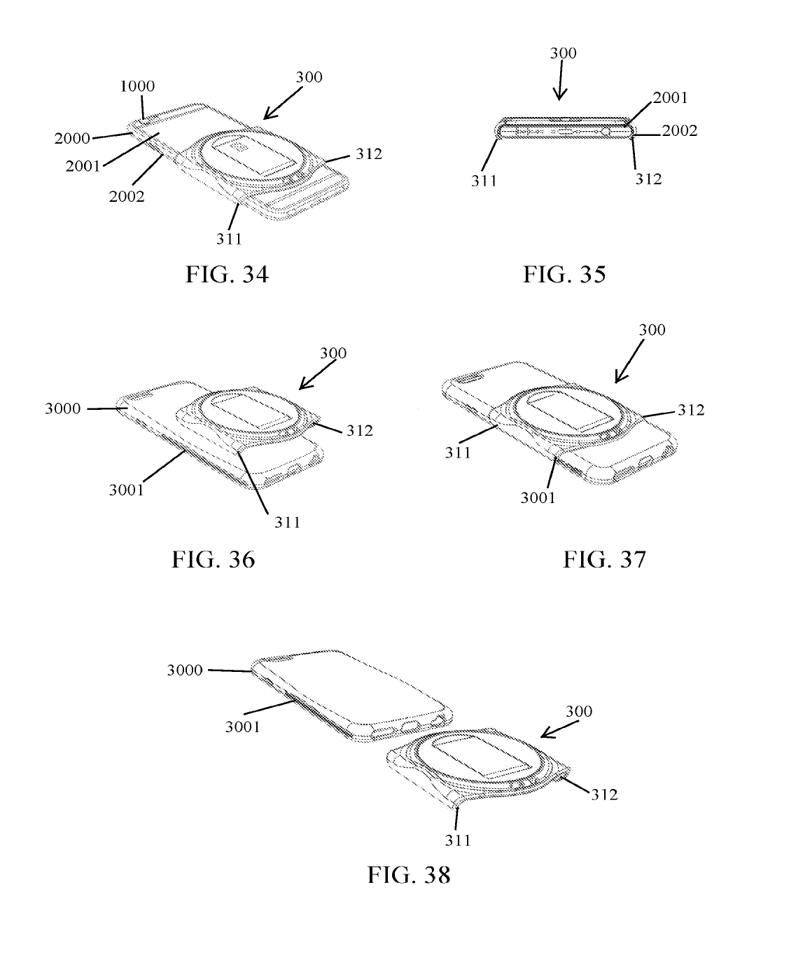

FIGS. 29-35 illustrate various views of the support and/or mount apparatus 300 being snap fit indirectly to a portable or mobile electronic device 1000 via a case 2000 surrounding a portion of the mobile electronic device 1000. Notably, engagement members 311, 312 can extend from a back edge 2001 of the case 2000 to and optionally past a front edge 2002 of the case 2000 in a side view and/or a top or bottom view. The engagement members 311, 312 can be snapped around respective opposite sides of the case 2000 to keep the support and/or mount apparatus 300 coupled to the case 2000. Not expressly illustrated, the same engagement members 311, 312 can be snapped around respective opposite sides of the mobile electronic device 1000 when case 2000 is not present to keep the support and/or mount apparatus 300 coupled to the mobile electronic device 1000. Of course, support and/or mount apparatus 400 can operate the same as discussed above for the support and/or mount apparatus 300 coupled to the mobile electronic device 1000, either directly or indirectly.

FIGS. 36-38 show various views of the support and/or mount apparatus 300 being coupled to a groove 3001 of a case 3000. Notably, engagement members 311, 312 can be snap fitted to groove 3001 as illustrated in FIG. 36 which shows the apparatus 300 at the back side of case 3000 about to be snap fitted to groove 3001 by pressing it onto the back of the case and/or slid into groove 3001 as a track as illustrated in FIG. 38, which shows apparatus 300 at the base of the case 3000 about to be slide up onto the bottom edge of case 3000 via groove 3001. Alternatively, depending upon the configuration of the groove 3001, the engagement members 311, 312 may only be able to be snap fit to the groove 3001, such as illustrated in FIG. 37 where the groove (not expressly shown) is sized to the dimensions of the engagement members 311, 312. Groove 3001 can also have a depression at a pre-defined location within the groove 3001 that is sized to the engagement members 311, 312 to locate apparatus 300 at a predefined specific or optimal location on the back of the case 3000. Of course, support and/or mount apparatus 400 can operate the same as discussed above for the support and/or mount apparatus 300 coupled to the mobile electronic device 1000.

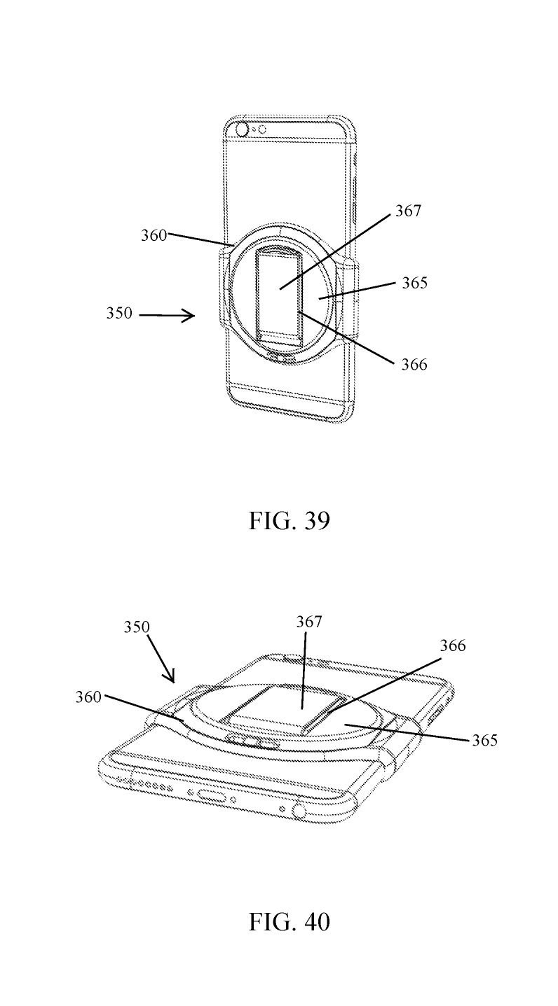

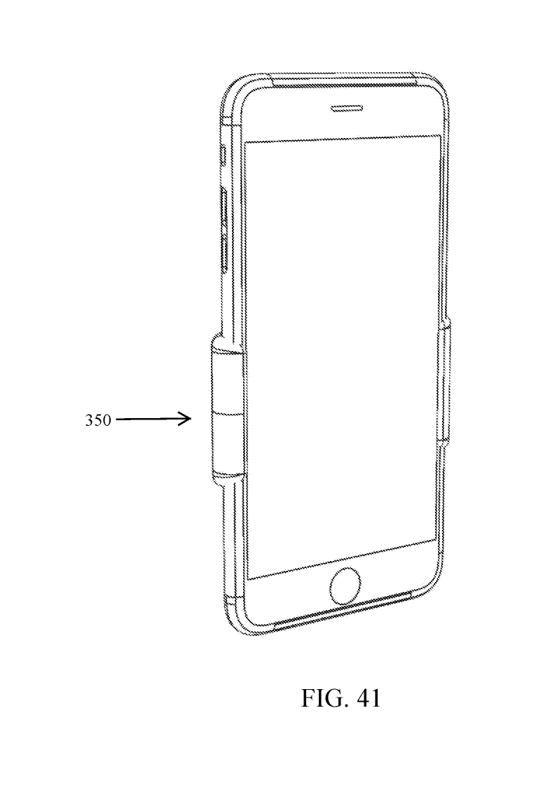

FIGS. 39-41 are various views of the support and/or mount apparatus 350 indirectly coupled to a portable electronic device through a case, where the support and/or mount apparatus 350 has a variation in the configuration of base structure 365, which may include a stand 366 with an elastic strap 367. Base structure 365, the base structure interface with body 360, the stand 366, and/or the elastic strap 367 can be based on, similar to, or the same as the respective components according to the disclosure of U.S. application Ser. No. 14/147,697.

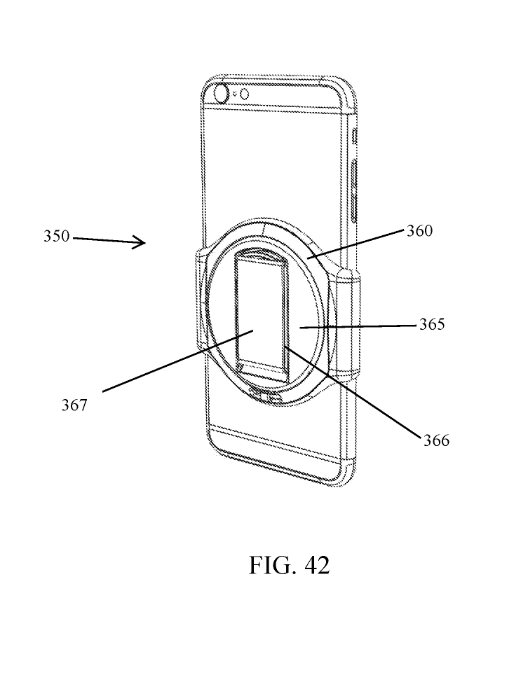

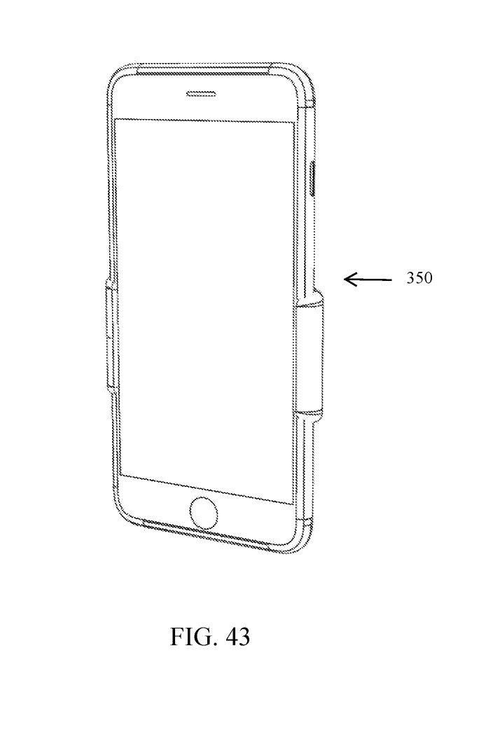

FIGS. 42 and 43 illustrate the support and/or mount apparatus 350 of FIGS. 39-41, but illustrate such apparatus being directly coupled (i.e., without an intervening case, for instance) to the portable electronic device.

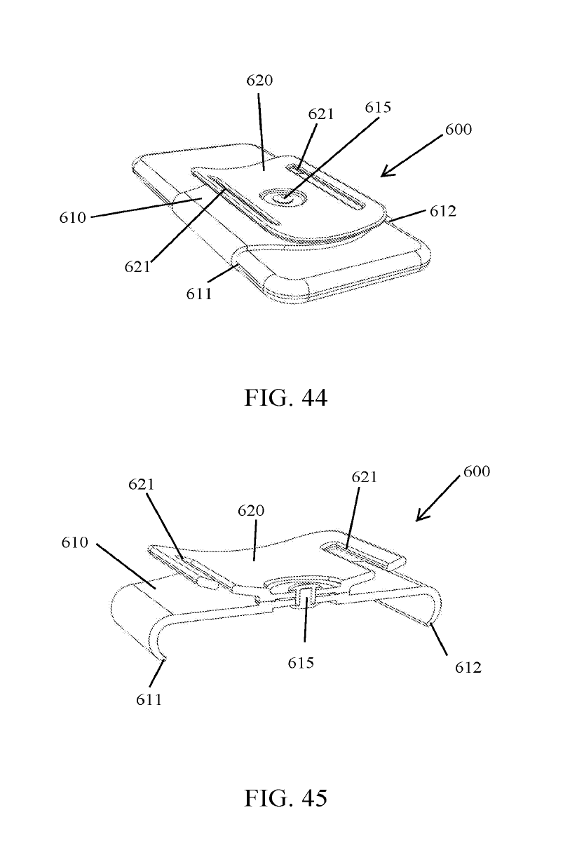

FIGS. 44 and 45 are various views of a support and/or mount apparatus 600 according to one or more embodiments of the disclosed subject matter. Notably, support and/or mount apparatus 600 includes a body 610 with engagement members 611, 612 and a mount structure 620 rotatably coupled to the body 610 about a rotatable interface 615. The mount structure 620, in turn, can be coupled to another component or components, such as a strap or band, via interfaces 621. Thus, the support and/or mount apparatus 600 can rotate relative to the mount structure 620, for instance, when the mount structure 620 is mounted to another structure, such as a body part of a wearer using a strap or band. Also, the support and/or mount apparatus 600 may not include a stand.

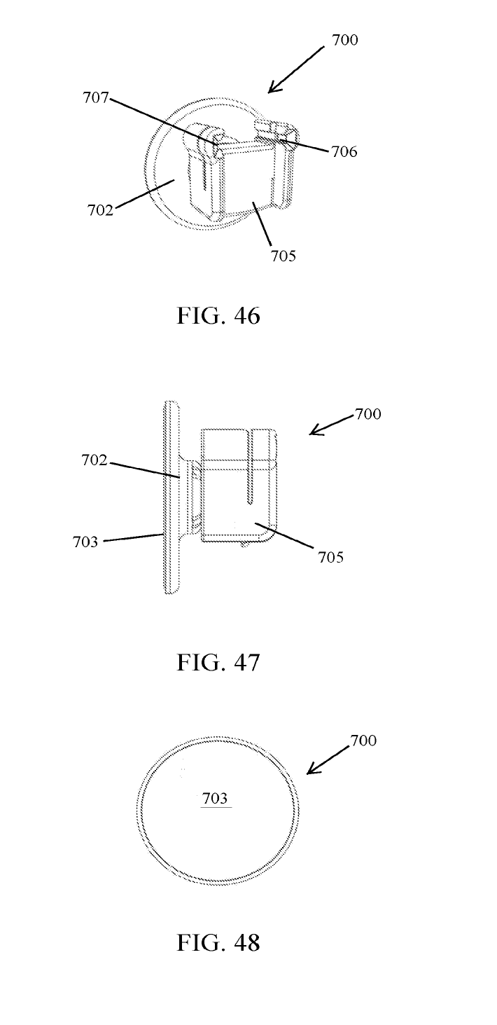

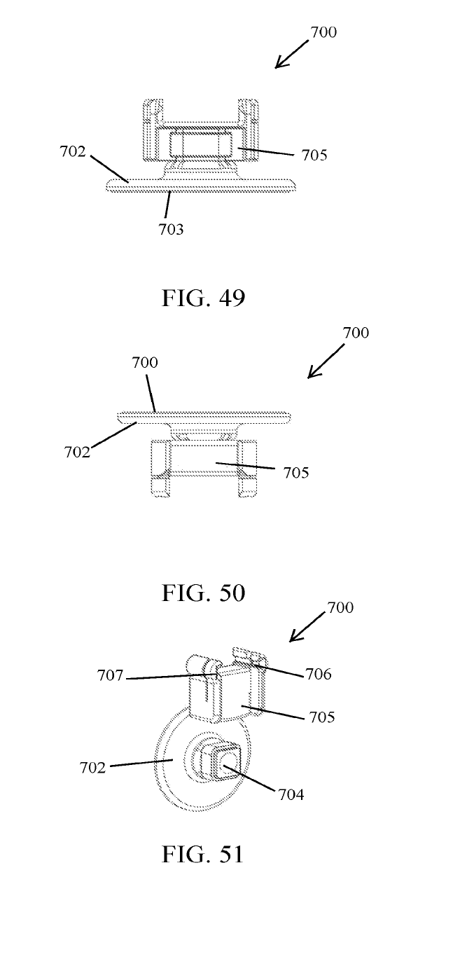

FIGS. 46-51 illustrate a non-limiting example of a mounting structure 700 according to one or more embodiments of the disclosed subject matter, with FIG. 51 showing an exploded view thereof. In particular, the mounting structure 700 can have a base 702 configured to be coupled to a surface of a structure by way of a face 703 of the base, which may be referred to herein as the first interface of mounting structure. The face 702 of the base 702 may be removably coupled, for instance, using a hoop and latch interlocking system, suction, or an adhesive to a portion of a structure, such as a dashboard or window of a vehicle, a mirror, a piece of gym equipment, etc. Alternatively, the face 702 of the base 702 may be substantially permanently coupled using an adhesive or alternatively using a magnetic material, for instance, to a portion of a structure, such as a dashboard or window of a vehicle, a mirror, a wall tile, a computer screen, a piece of gym equipment, etc.

The mounting structure 700 can also include a mounting structure 705, which may be removably coupled to base 702 via connector 703. Mounting structure 705 can be removably coupled to a mount connection of a support system, for instance, a rotatable stand of support and/or mount apparatuses according to the present disclosure. More specifically, a stand of a support and/or mount apparatus can be rotated from its fully retracted position and its free end inserted into opposing tracks 706, 707 of mounting structure 705.

While aspects of the present disclosure have been particularly shown and described with reference to the embodiments above, it will be understood by those skilled in the art that various additional embodiments may be contemplated by the modification of the disclosed machines, systems and methods without departing from the scope of what is disclosed. Such embodiments should be understood to fall within the scope of the present disclosure as determined based upon the claims and any equivalents thereof.

What is claimed is:

1. A support system configured to serve as one or both of a mount connection and a surface support for a mobile electronic device, comprising:
a body configured to be coupled to the mobile electronic device, one of directly, indirectly, and each of directly and indirectly, separately, at a first interface; and
a base structure rotatably connected to the body configured to be coupled to a separable mounting structure for the mount connection of the support system, different from the mobile electronic device, at a second interface different from the first interface.

2. The support system of claim 1, wherein the body is removably coupleable to the mobile electronic device.

3. The support system of claim 1, wherein the base structure includes a stand rotatable about a first axis.

4. The support system of claim 3, wherein the base structure and the stand are rotatable about a second axis in a plane perpendicular to a plane of the first axis.

5. The support system of claim 1, wherein the mounting structure is configured to be removably coupled to a portion of a wearer's body.

6. The support system of claim 1, wherein the body is configured to be coupled to the mobile electronic device, separately directly and indirectly, by snapping over opposite sides of the mobile electronic device.

7. The support system of claim 6, wherein the opposite sides are long sides of the mobile electronic device, and the body does not extend to either opposite short side of the mobile electronic device.

8. The support system of claim 6, wherein the opposite sides are long sides of the mobile electronic device, and the body does not snap over opposite short sides of the mobile electronic device.

9. The support system of claim 1, wherein the body is configured to be coupled to the mobile electronic device, directly and indirectly, sliding into at least one groove on a side of the mobile electronic device or a case over the mobile electronic device.

10. The support system of claim 1, wherein base structure is a stand that is rotatable about a first axis through or parallel with a back surface of the mobile electronic device.

11. The support system of claim 1, wherein the body is substantially fixed to the mobile electronic device and forms part of the mobile electronic device.

12. An apparatus configured to serve as a mount connection and a surface support for a portable electronic device with a display screen, comprising:
a body configured to be selectively and individually coupled to the portable electronic device and to a case over the portable electronic device, by snapping over and/or sliding onto, directly and indirectly, only a first set of opposite sides of the portable electronic device and not a second set of opposite sides of the portable electronic device; and
a base structure rotatably connected to the body configured to be coupled to a separable mounting structure, different from the portable electronic device, at a second interface different from the first interface,
wherein the portable electronic device, the apparatus, and the mounting structure are distinct components,
wherein the portable electronic device is separable from the body of the apparatus when the base structure is coupled to the mounting structure,
wherein the base structure of the apparatus is separable from the mounting structure when the portable electronic device is coupled to the body, either directly or indirectly, and
wherein the portable electronic device portable electronic device is separable from the body of the apparatus and the base structure of the apparatus is separable from the mounting structure.

13. The apparatus of claim 12, wherein the first set of opposite sides are long sides of the portable electronic device.

14. The apparatus of claim 12, wherein the base structure includes a stand rotatable about a first axis.

15. The apparatus of claim 14, wherein the base structure is rotatable relative to the base structure about a second axis in a plane perpendicular to a plane of the first axis.
